(19) United States
(12) Patent Application Publication
(10) Pub. No.: US 2024/0364056 A1
(43) Pub. Date: Oct. 31, 2024

(54) CONNECTOR ASSEMBLY

(71) Applicant: MOLEX, LLC, Lisle, IL (US)

(72) Inventors: Che-Yuan Yang, New Taipei City (TW); Ya-Li Xu, New Taipei City (TW)

(21) Appl. No.: 18/644,166

(22) Filed: Apr. 24, 2024

(30) Foreign Application Priority Data
Apr. 28, 2023 (CN) 202310486344.7
Apr. 9, 2024 (CN) 202410421270.3

(51) Int. Cl. H01R 13/6581; H01R 13/629

(52) U.S. Cl. CPC H01R 13/6581; H01R 13/629

(57) ABSTRACT

A connector assembly includes a guide shielding cage and a heat sink module. The guide shielding cage includes a cage body which has an inserting passageway, and a heat sink bracket which is positioned above the inserting passageway of the cage body. The heat sink module is provided to the heat sink bracket, the heat sink module includes a heat sink, a pressure-applying spring and a restoring spring; the heat sink has a pushed portion which extends into the inserting passageway, the pressure-applying spring is provided between the top plate of the heat sink bracket and the heat sink, the heat sink and the heat sink bracket are provided therebetween with a guiding construction, the guiding construction guides the heat sink to move between a first position which is at relative front and up and a second position which is at relative rear and down. When the pluggable module inserts into the inserting passageway of the guide shielding cage, the pluggable module pushes the pushed portion of the heat sink and makes the heat sink move from the first position to the second position, at the same time, an elastic acting force of the pressure-applying spring makes a bottom portion of the heat sink downwardly contact a surface of the pluggable module with an elastic pressure. When the pluggable module is withdrawn, the restoring spring drives the heat sink to move back to the first position.

### RELATED APPLICATIONS

The present application claims priority to Chinese patent application no. 202310486344.7 filed on Apr. 28, 2023 and Chinese patent application no. 202410421270.3 filed on Apr. 9, 2024, both of which are incorporated by reference in their entireties.

### TECHNICAL FIELD

The present disclosure relates to a connector assembly, and particularly relates to a connector assembly which has a heat sink.

### BACKGROUND

Chinese patent document CN110296628A (corresponding to U.S. Pat. No. 10,651,598B2) discloses a heat exchange structure, which includes a metal member, a lever and a frame, the frame is used to support the lever and the metal member, a front end of the metal member is fixed on a front edge of the frame by a fastener such as a rivet. When a heat source slides relative to a heat sink, the heat source contacts one end of the lever to actuate the other end of the lever to contact a rear end of the metal member, the metal member downwardly pushes the heat sink and a thermal conductive pad to contact the heat source.

However, this prior art needs to additionally provide the one frame which is used to mount the lever and the metal member. And the metal member needs to be provided on a top surface of the heat sink, thereby resulting in that the heat sink needs to open a groove which is used to mount the metal member, lowering a heat dissipating area of the heat sink. And, the metal member only uses a single point (screw) to engage with the heat sink, when the lever is pushed, the lever presses down on the rear end of the metal member, which would make the heat sink easily skewed. Moreover, the metal member needs a space which can permit the metal member to elastically deform and move up and down, together with that the lever needs an up-down pace and a front-rear space which can permit the lever to rotate and swing, so a large amount of a space of the heat sink is occupied, and it is difficult to make the entire of the heat sink thinned.

U.S. Pat. No. 10,222,844B1 discloses that oblique surfaces which are oblique as sliding profile ramps are provided on a top side of a cage, guide pins of a heat sink move along the oblique sliding profile ramps, the heat sink is downwardly pressed against a replaceable electronic module to establish thermal contact, and a leaf spring is provided to a rear surface of the cage, when the leaf spring is released, the heat sink is pushed to front ends of the sliding profile ramps, so that the replaceable electronic module is pushed out from an inside of the cage to an outside of the cage.

However, the sliding profile ramps disclosed in such a prior art are long strip channels in shape, so movement of the heat sink is completely depended on limiting from oblique angles and lengths of the long strip channels and widths of the long strip channels, a contact pressure between the heat sink and the electronic module is also completely depended on movement of the guide pins on the long strip channels, as such, the heat sink in an oblique direction directly presses on a surface of the electronic module with hard interference, if the interference is too much, the too much interference may hinder inserting of the electronic module, even may damage a thermal interface material, if the interference is too less, the too less interference may affect a contact area and a heat dissipating efficacy of a heat dissipating interface. In addition, the leaf spring in such a prior art is provided to the rear surface of the cage, the heat sink cannot elongate rearwardly, a length and the heat dissipating efficacy of the heat sink are limited. Moreover, the sliding profile ramps and the leaf spring are integrally constructed on the cage, so complexity, difficulty and cost of manufacturing are increased.

### SUMMARY

Therefore, an object of the present disclosure is to provide a connector assembly which can improve at least one problem of prior art.

Accordingly, in some embodiments, a connector assembly of the present disclosure is adapted to mate with a pluggable module, the connector assembly comprises a guide shielding cage and a heat sink module. The guide shielding cage comprises a cage body which has an inserting passageway, and a heat sink bracket which is positioned above the inserting passageway of the cage body, the heat sink bracket has a top plate. The heat sink module is provided to the heat sink bracket, the heat sink module comprises a heat sink, a pressure-applying spring and a restoring spring; the heat sink has a pushed portion which extends into the inserting passageway, the pressure-applying spring is provided between the top plate of the heat sink bracket and the heat sink, the restoring spring is provided between the heat sink bracket and the heat sink, the heat sink and the heat sink bracket are provided therebetween with a guiding construction, the guiding construction guides the heat sink to move between a first position which is at relative front and up and a second position which is at relative rear and down. When the pluggable module inserts into the inserting passageway of the guide shielding cage along an inserting direction from front to rear, the pluggable module pushes the pushed portion of the heat sink and makes the heat sink move from the first position to the second position, when the heat sink is at the second position, an elastic acting force of the pressure-applying spring makes a bottom portion of the heat sink downwardly contact a surface of the pluggable module with an elastic pressure. When the pluggable module is withdrawn from the inserting passageway, the restoring spring drives the heat sink to move from the second position back to the first position.

In some embodiments, the heat sink bracket further has side plates, the guiding construction comprises guiding pins and guiding rails which cooperate with each other, the guiding rails are constructed to the side plates of the heat sink bracket and obliquely extend rearwardly and downwardly, the guiding pins are constructed to side surfaces of the heat sink, the guiding pins are capable of moving along the guiding rails respectively.

In some embodiments, the guiding construction further comprises guiding holes which are constructed to the side plates of the heat sink bracket and accommodate the guiding pins respectively, the guiding hole has the guiding rail constituted by a lower profile of the guiding hole, and a positioning rail which is positioned in front of and above the guiding rail and extends forwardly, when the heat sink is positioned at the first position, at least a part of the guiding pin is positioned in the corresponding positioning rail.

In some embodiments, the pressure-applying spring comprises plate springs which integrally constructed to the top plate of the heat sink bracket, the plate springs extend rearwardly and downwardly; the heat sink is constructed with pressure-applying spring acting portions, when the heat sink moves rearwardly and downwardly from the first position, the pressure-applying spring acting portions actuate the pressure-applying spring to be elastically deformed so that the pressure-applying spring generates and applies a downward elastic force to the pressure-applying spring acting portions.

In some embodiments, the heat sink has heat dissipating fins, the pressure-applying spring acting portions are constructed on the heat dissipating fins of the heat sink, and comprise oblique pushing surfaces which extend rearwardly and downwardly.

In some embodiments, the heat sink has a base seat, the pressure-applying spring acting portions are constructed on the base seat and comprise oblique pushing surfaces which extend rearwardly and downwardly.

In some embodiments, the restoring spring is provided between a front end of the heat sink bracket and a front end of the heat sink, when the heat sink moves rearwardly, the restoring spring is elastically deformed so as to provide an elastic acting force which makes the heat sink move to the first position.

In some embodiments, the heat sink bracket has a first hook portion which is positioned at the front end of the heat sink bracket, the heat sink has a second hook portion is positioned at the front end of the heat sink, a front end of the restoring spring connects the first hook portion at the front end of the heat sink bracket, a rear end of the restoring spring connects the second hook portion at the front end of the heat sink.

In some embodiments, the heat sink bracket further has a side plate, the heat sink further has a side portion, the restoring spring is provided between the side plate of the heat sink bracket and the side portion of the heat sink, when the heat sink moves rearwardly, the restoring spring is elastically deformed so as to provide an elastic acting force which makes the heat sink move to the first position.

In some embodiments, the side plate of the heat sink bracket has a first hook portion, the side portion of the heat sink has a notch and a second hook portion which is positioned behind the notch, the first hook portion extends into the notch, the restoring spring is positioned in the notch, a front end of the restoring spring connects the first hook portion, a rear end of the restoring spring connects the second hook portion.

In some embodiments, the restoring spring is constructed as a coil spring, when the heat sink moves rearwardly, the restoring spring is stretched to be elastically deformed.

In some embodiments, when the heat sink is positioned at the first position, the bottom portion of the heat sink does not contact the surface of the pluggable module.

In some embodiments, the heat sink further has a base seat, heat dissipating fins which are provided a top surface of the base seat, and a thermal contact portion which protrudes downwardly from a bottom surface of the base seat, the pushed portion is positioned at a rear end of the thermal contact portion, the pushed portion extends downwardly from the bottom surface of the base seat to a position which is lower than the thermal contact portion.

In some embodiments, the thermal contact portion of the heat sink comprises a thermal conductive pad.

In some embodiments, the heat sink bracket comprises an upper frame and a lower frame, the upper frame has the top plate and first side plates, the lower frame has a bottom plate and second side plates, the first side plates of the upper frame and the second side plates of the lower frame are provided therebetween with a latching construction which allows the first side plates of the upper frame and the second side plates of the lower frame to latch with each other and an aligning construction which allows the first side plates of the upper frame and the second side plates of the lower frame to mate with each other.

In some embodiments, the latching construction comprises latching pieces and latching holes which latch with each other, the latching pieces are provided on the second side plates of the lower frame, the latching holes are provided on the first side plates of the upper frame; the aligning construction comprises aligning pieces and aligning holes which mate with each other, the aligning pieces are provided to upper edges of the second side plates of the lower frame and extend upwardly, the aligning holes are provided to the top plate of the upper frame at locations of the top plate of the upper frame which are respectively close to the first side plates, the first side plates of the upper frame are positioned at outer sides of the second side plates of the lower frame respectively, the aligning pieces insert into the aligning holes respectively; a position-limiting piece is provided at an inner side of the corresponding aligning hole and is recessed, the position-limiting piece is lower than a position of a top portion of the corresponding aligning piece.

In some embodiments, the position-limiting piece which is recessed has a protruding edge which extends toward corresponding the aligning piece.

In some embodiments, the cage body of the guide shielding cage further has a top wall and side walls which together define the inserting passageway, the heat sink bracket further has a bottom plate and side plates, the heat sink bracket is provided to the top wall, the heat sink bracket and the cage body are provided therebetween with a bracket assembling construction, the bracket assembling construction comprises a bottom assembling construction, a side assembling construction and a rear assembling construction, the bottom assembling construction is provided between a left side and a right side of the bottom plate of the heat sink bracket and a left side and a right side of the top wall of the cage body, the side assembling construction is provided between the side plates of the heat sink bracket and the side walls of the cage body, the rear assembling construction is provided between a rear end of the bottom plate of the heat sink bracket and the top wall of the cage body.

In some embodiments, the bottom assembling construction comprises snapping hooks which extend out from the top wall of the cage body, the bottom plate of the heat sink bracket snaps onto the snapping hooks.

In some embodiments, the bottom assembling construction further comprises snapping hook apertures which are constructed to the bottom plate of the heat sink bracket, openings of the snapping hooks are toward the front, after the snapping hooks pass through the snapping hook apertures, the heat sink bracket moves rearwardly, so as to make the bottom plate snap into the snapping hooks.

In some embodiments, the side assembling construction comprises side extending pieces which extend from the side plates of the heat sink bracket to outer sides of the side walls of the cage body and inserting pieces which protrude rearwardly from the side extending pieces respectively, bulges which are formed to the side walls of the cage body, and inserting holes which are constructed to the bulges and are opened toward the front, the inserting pieces rearwardly insert into the inserting holes respectively.

In some embodiments, the rear assembling construction comprises a rear latching piece which extends downwardly from a rear end of the bottom plate of the heat sink bracket, and a rear latching groove which is formed to the top wall of the cage body, the rear latching piece is used to downwardly latch to the rear latching groove.

In some embodiments, the bracket assembling construction further comprises a sideward position-limiting construction which is provided between the two sides of the bottom plate of the heat sink bracket and the side walls of the cage body; the sideward position-limiting construction comprises sideward position-limiting pieces which bend downwardly from the two sides of the bottom plate of the heat sink bracket and are respectively positioned to outer sides of the two side walls of the cage body.

In the present disclosure, by that the pressure-applying spring, which is provided between the heat sink bracket and the heat sink, directly applies an elastic force to the heat sink, and by that the guiding construction, which is between the heat sink and the heat sink bracket, pushes and guides the heat sink to move rearwardly and downwardly to the second position, as such, after inserting of the pluggable module, can the heat sink move to a position where the heat sink contacts the surface of the pluggable module, so as to avoid the bottom portion of the heat sink and the pluggable module therebetween generating a friction situation in an inserting process of the pluggable module, prevent wearing problem of the bottom portion of the heat sink, or prevent the thermal interface material provided to the bottom portion of the heat sink from being scratched. In addition, the pressure-applying spring is integrally constructed on the heat sink bracket, the pressure-applying spring acting portions 315 are integrally constructed on the heat sink (the heat dissipating fins), which makes an entire heat dissipating assembly simplified and has a constructive effect of low profile. Furthermore, because the guiding construction only provides a guiding function, but the pressure-applying spring directly acts on the heat sink, so that the bottom portion of the heat sink contacts the surface of the pluggable module with the elastic pressure, heat conduction efficiency can be promoted and heat dissipating effect is increased, and hard interference situation between the heat sink 31 and the pluggable module is prevented.

### BRIEF DESCRIPTION OF THE DRAWINGS

Other features and effects of the present disclosure will be apparent from embodiments with reference to the drawings, in which:

FIG. 1 is a perspective view of a first embodiment of a connector assembly of the present disclosure and a pluggable module;

FIG. 2 is a perspective exploded view of the first embodiment;

FIG. 3 is a perspective exploded view of the first embodiment viewed from another angle;

FIG. 4 is a perspective view of a guide shielding cage of the first embodiment, in which an upper frame of a heat sink bracket of the guide shielding cage flips open upwardly relative to a lower frame;

FIG. 5 is a perspective exploded view of the heat sink bracket and a heat sink module of the first embodiment, in which the upper frame of the heat sink bracket flips open upwardly relative to the lower frame;

FIG. 6 is a perspective exploded view of the heat sink bracket and the heat sink module of the first embodiment of FIG. 5 viewed from another angle;

FIG. 7 is a perspective view of the first embodiment, in which a heat sink of the heat sink module of the first embodiment is positioned at a first position;

FIG. 8 is a partially enlarged perspective view of a region A1 of FIG. 7;

FIG. 9 is a partially cut away perspective view of the first embodiment, in which the heat sink of the heat sink module of the first embodiment is positioned at the first position;

FIG. 10 is a top view of the first embodiment, in which the heat sink of the heat sink module of the first embodiment is positioned at the first position;

FIG. 11 is a cross sectional view taken along a line A-A of FIG. 10;

FIG. 12 is a perspective view of the first embodiment and the pluggable module, in which the heat sink of the heat sink module of the first embodiment is pushed to a second position by the pluggable module which inserts into the guide shielding cage;

FIG. 13 is a partially cut away perspective view of the first embodiment, in which the heat sink of the heat sink module of the first embodiment is positioned at the second position;

FIG. 14 is a top view of the first embodiment and the pluggable module, in which the heat sink of the heat sink module of the first embodiment is pushed to the second position by the pluggable module which inserts into the guide shielding cage;

FIG. 15 is a cross sectional view taken along a line B-B of FIG. 14;

FIG. 16 is a perspective view of a second embodiment of the connector assembly of the present disclosure;

FIG. 17 is a perspective exploded view of the heat sink bracket and the heat sink module of the second embodiment;

FIG. 18 is a perspective view of a third embodiment of the connector assembly of the present disclosure;

FIG. 19 is a perspective exploded view of the third embodiment;

FIG. 20 is a perspective exploded view of the third embodiment further exploded;

FIG. 21 is a perspective exploded view of the guide shielding cage of the third embodiment;

FIG. 22 is a perspective exploded view of the heat sink bracket and a base seat of a heat sink of the third embodiment;

FIG. 23 is a perspective exploded view of the heat sink of the third embodiment.

### DETAILED DESCRIPTION

Before the present disclosure is described in detail, it is noted that the similar elements are indicated by the same reference numerals in the following description.

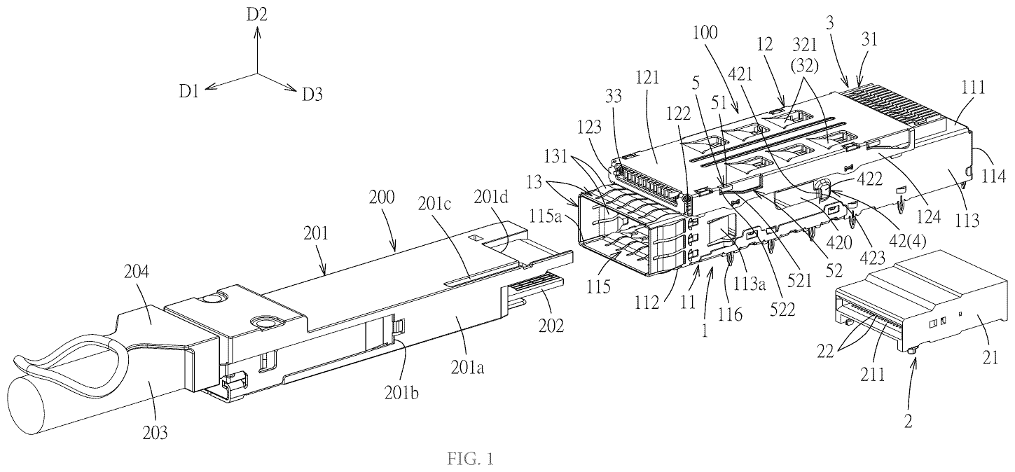

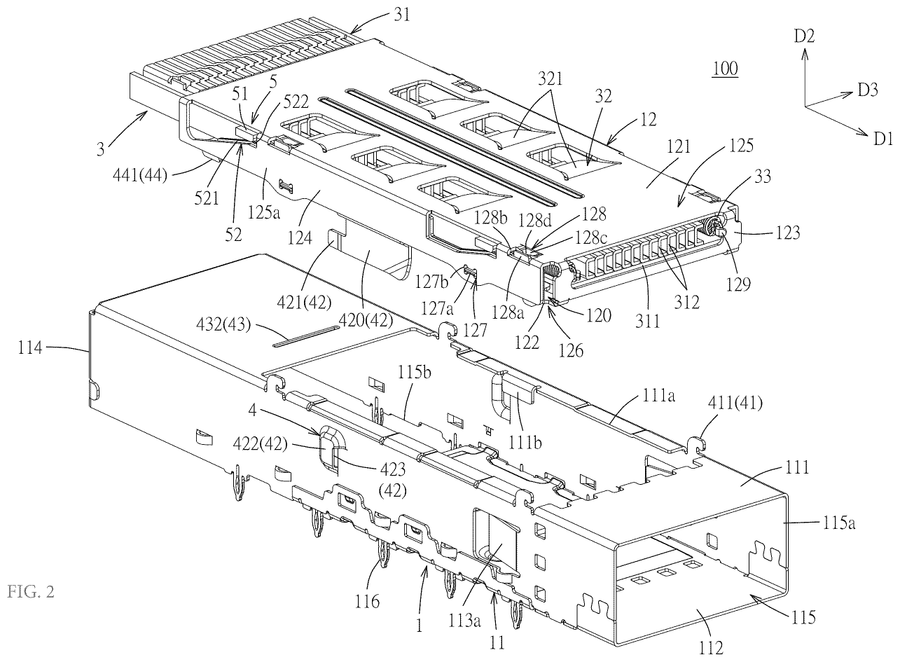

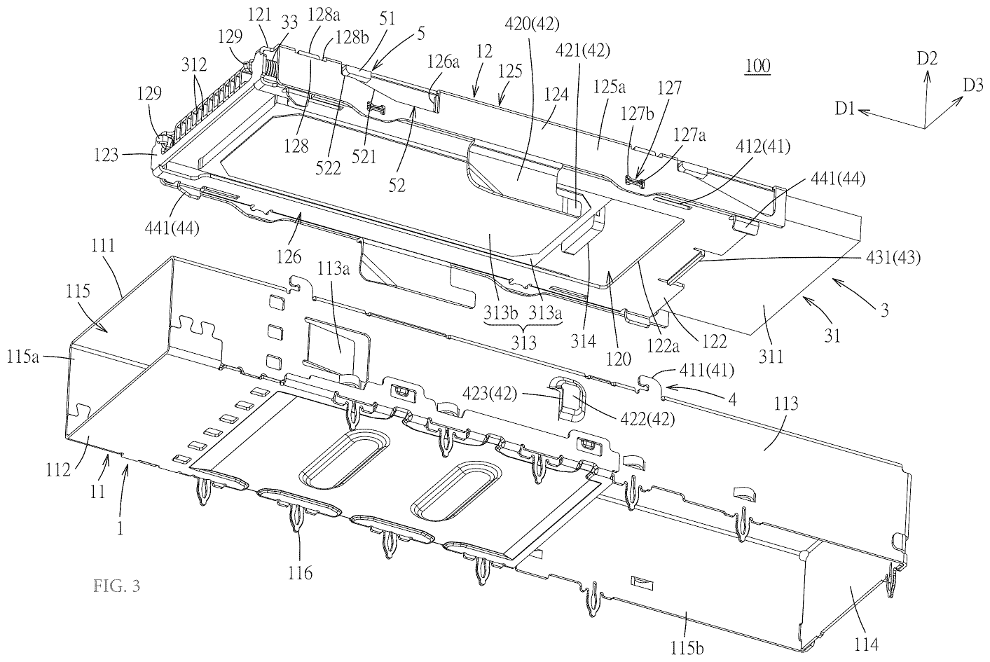

Referring to FIG. 1 to FIG. 4, a first embodiment of a connector assembly 100 of the present disclosure is adapted to mate with a pluggable module 200. The pluggable module 200 has a shell member 201, a mating circuit board 202 and a cable 203. The shell member 201 has an inserting portion 201a, the mating circuit board 202 is provided to a tip of the inserting portion 201a, the cable 203 is provided to the shell member 201 and is electrically connected to the mating circuit board 202. The connector assembly 100 includes a guide shielding cage 1, a receptacle connector 2 and a heat sink module 3.

The guide shielding cage 1 includes a cage body 11 and a heat sink bracket 12 provided to the cage body 11. The cage body 11 and the heat sink bracket 12 are for example constructed by a metal plate, are for example formed by processing, such as stamping and bending, a metal thin plate via a mold. The cage body 11 is used to be provided to a board (for example a circuit board (not shown)) and extends along a front-rear direction D1 (a direction to which an arrow points is front, and an opposite direction is rear). The cage body 11 has a top wall 111 and a bottom wall 112 which are spaced apart from each other along an up-down direction D2 (a direction to which an arrow points is up, and an opposite direction is down), two side walls 113 which are spaced apart from each other along a left-right direction D3 (a direction to which an arrow points is right, and an opposite direction is left), a rear wall 114 which is positioned at a rear end of the cage body 11 along the front-rear direction D1, and an inserting passageway 115 which is defined together by the top wall 111, the bottom wall 112, the two side walls 113 and the rear wall 114 and is positioned inside the cage body 11. The two side walls 113 and the rear wall 114 are constructed with a plurality of inserting legs 116 which extend downwardly and are adapted to be fixed on the circuit board and/or be connected to grounding trace (not shown). The inserting passageway 115 has a front end port 115a which is toward the front and allows the inserting portion 201a of the pluggable module 200 to insert therein, and a bottom portion opening 115b which is positioned behind a bottom portion of the inserting passageway 115.

The top wall 111 of the cage body 11 has a window 111a which is communicated to the inserting passageway 115, and a guiding portion 111b which extends downwardly from a rear segment of a side of the window 111a into the inserting passageway 115. Each side wall 113 of the cage body 11 has an inward extending elastic piece 113a which is positioned in the front of the side wall 113.

The cage body 11 is assembled with a plurality of grounding members 13 around the front end port 115a. In the present embodiment, the cage body 11 of the connector assembly 100 may be provided to a mounting hole (not shown) of a casing (not shown), each grounding member 13 has a plurality of elastic portions 131 which extend rearwardly and are distributed to an outer side and an inner side of the cage body 11, the elastic portion 131 of the plurality of elastic portions 131 which is positioned at the outer side of the cage body 11 is used to contact the mounting hole of the casing, the elastic portion 131 of the plurality of elastic portions 131 which is positioned at the inner side of the cage body 11 is used to contact the pluggable module 200.

The receptacle connector 2 is mechanically and electrically provided to the circuit board, the receptacle connector 2 has a housing 21 which is insulative and a plurality of terminals 22, the housing 21 has a mating slot 211 which is opened toward the front, the plurality of terminals 22 are provided in the mating slot 211 and have tail portions thereof (not shown) to be electrically and mechanically connected to the circuit board. The receptacle connector 2 is provided to a rear segment of the inserting passageway 115 via the bottom portion opening 115b so as to be covered by the cage body 11, but the present disclosure is not limited thereto. In another implementing manner, the receptacle connector 2 may be assembled into the cage body 11 from the rear end of the cage body 11 of the guide shielding cage 1, the tail portions of the plurality of terminals 22 may be electrically and mechanically connected to wires (not shown) respectively and the wires extend out of the rear end of cage body 11 of the guide shielding cage 1 so as to be connected to another device (not shown).

The inserting portion 201a of the pluggable module 200 has two locking recessed grooves 201b which are positioned at a left side and a right side of the inserting portion 201a, a guiding groove structure 201c which is positioned at a top portion of a front end of the inserting portion 201a, and a pushing surface 201d which is positioned at the top portion of the front end of the inserting portion 201a and is toward the front. The two inward extending elastic pieces 113a of the two side walls 113 of the cage body 11 are used to cooperate with the two locking recessed grooves 201b of the pluggable module 200 which inserts into the inserting passageway 115 so as to generate a locking effect. The guiding portion 111b of the top wall 111 of the cage body 11 is used to cooperate with the guiding groove structure 201c of the pluggable module 200 which inserts into the inserting passageway 115 so as to generate a guiding function. In addition, the pluggable module 200 further has a locking release member 204, the two inward extending elastic piece 113a are capable of being pushed out of the two locking recessed grooves 201b when the locking release member 204 is pulled.

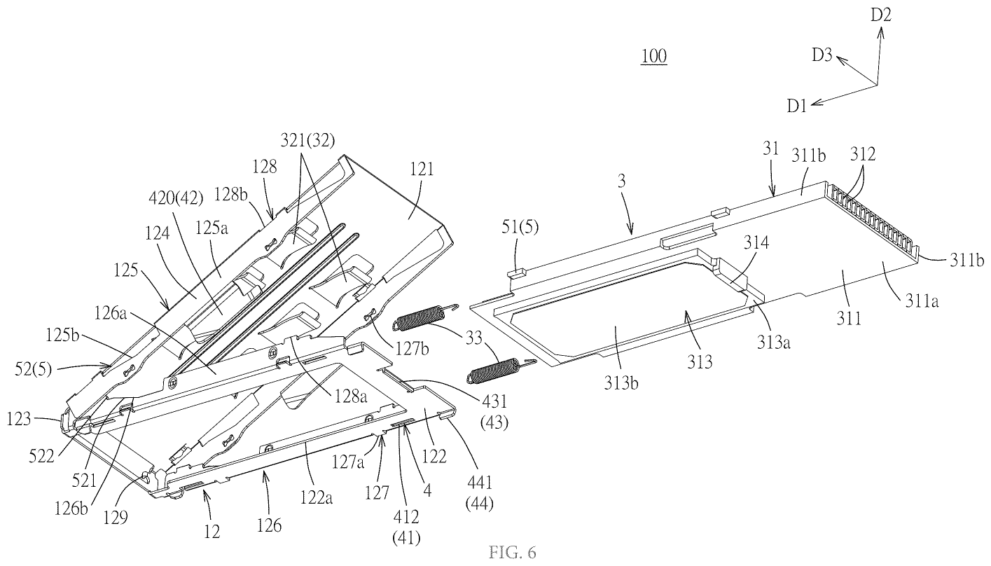

Referring to FIG. 1 and FIG. 4 to FIG. 6, the heat sink bracket 12 of the guide shielding cage 1 is positioned above the inserting passageway 115 and is provided to the top wall 111 of the cage body 11 of the guide shielding cage 1. The heat sink bracket 12 has a top plate 121 and a bottom plate 122 which face each other along the up-down direction D2, a front connecting plate 123 which is connected between a front edge of the top plate 121 and a front edge of the bottom plate 122, two side plates 124 which face each other along the left-right direction D3, and a heat sink receiving space 120 which is defined together by the top plate 121, the bottom plate 122, the front connecting plate 123 and the two side plates 124. The bottom plate 122 has a frame mouth 122a which is communicated with the heat sink receiving space 120 and corresponds to the window 111a of the top wall 111. In the first embodiment, the heat sink bracket 12 includes an upper frame 125 and a lower frame 126. The upper frame 125 has the top plate 121 and two first side plates 125a which extend downwardly from a left side and a right side of the top plate 121 respectively, the lower frame 126 has the bottom plate 122 and two second side plates 126a which extend upwardly from a left side and a right side of the bottom plate 122 respectively, the upper frame 125 and the lower frame 126 are integrally connected by the front connecting plate 123 which is positioned at a front end of the heat sink bracket 12. The two first side plates 125a of the upper frame 125 and the two second side plates 126a of the lower frame 126 are provided therebetween with a latching construction 127 which allows the two first side plates 125a of the upper frame 125 and the two second side plates 126a of the lower frame 126 to latch with each other and an aligning construction 128 which allows the two first side plates 125a of the upper frame 125 and the two second side plates 126a of the lower frame 126 to mate with each other, so that the two first side plates 125a respectively engage with the two second side plates 126a. The two first side plates 125a of the upper frame 125 are positioned at outer sides of the two second side plates 126a of the lower frame 126 respectively, the two first side plates 125a and the two second side plates 126a together constitute the two side plates 124 of the heat sink bracket 12.

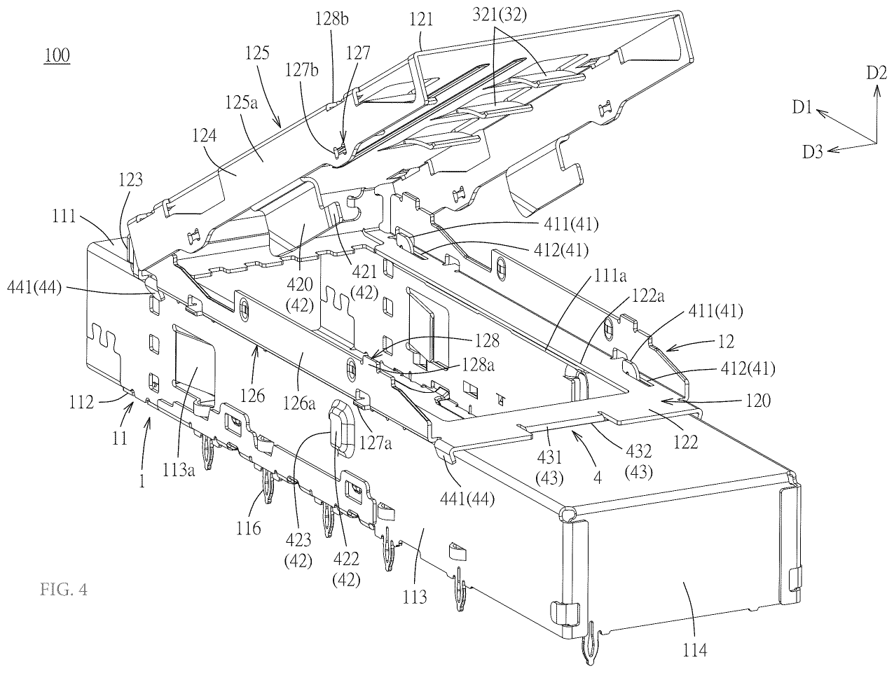

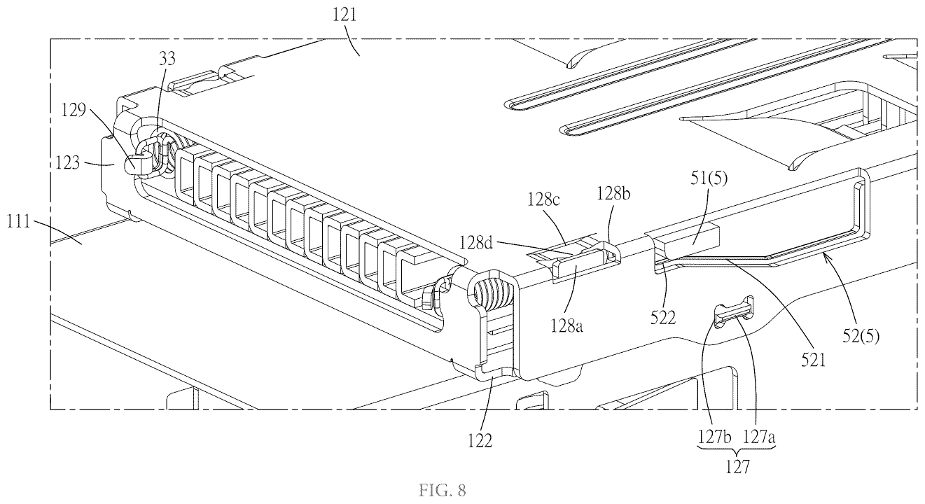

Referring to FIG. 4 to FIG. 8, the latching construction 127 includes latching pieces 127a and latching holes 127b which are respectively provided to two sides of the heat sink bracket 12 and latch with each other, the two second side plates 126a of the lower frame 126 are respectively provided with the latching pieces 127a, the two first side plates 125a of the upper frame 125 are respectively provided with the latching holes 127b. The aligning construction 128 includes aligning pieces 128a and aligning holes 128b which are respectively provided to the two sides of the heat sink bracket 12 and mate with each other, upper edges of the two second side plates 126a of the lower frame 126 are respectively provided with the aligning pieces 128a which extend upwardly, the top plate 121 of the upper frame 125 is provided with the aligning holes 128b at locations of the top plate 121 of the upper frame 125 which are respectively close to the two first side plates 125a. Each aligning piece 128a inserts into the respective aligning hole 128b, a position-limiting piece 128c is provided at an inner side of each aligning hole 128b, is recessed downwardly and is constructed to the top plate 121 of the upper frame 125, the position-limiting piece 128c is lower than a position of a top portion of the corresponding aligning piece 128a, and the position-limiting piece 128c which is recessed has a protruding edge 128d which extends toward the corresponding aligning piece 128a. By the latching construction 127 and the aligning construction 128, the upper frame 125 and the lower frame 126 can be indeed fixed and aligned so as to avoid the heat sink bracket 12 being deformed.

The heat sink bracket 12 and the cage body 11 are provided therebetween with a bracket assembling construction 4, the bracket assembling construction 4 includes a bottom assembling construction 41, a side assembling construction 42, a rear assembling construction 43 and a sideward position-limiting construction 44.

The bottom assembling construction 41 is provided between the left side and the right side of the bottom plate 122 of the heat sink bracket 12 and a left side and a right side of the top wall 111 of the cage body 11. The bottom assembling construction 41 includes snapping hooks 411 which extend out from the top wall 111 of the cage body 11, and snapping hook apertures 412 which are constructed to the bottom plate 122 of the heat sink bracket 12 and respectively correspond to the snapping hooks 411. Openings of the snapping hooks 411 are toward the front, after the snapping hooks 411 respectively pass through the snapping hook apertures 412, the heat sink bracket 12 moves rearwardly, so as to make the bottom plate 122 of the heat sink bracket 12 snap into the openings of the snapping hooks 411 and in turn snap to the snapping hooks 411.

The side assembling construction 42 is provided between the two side plates 124 of the heat sink bracket 12 and the two side walls 113 of the cage body 11. The side assembling construction 42 includes two side extending pieces 420 which respectively extend from the two side plates 124 of the heat sink bracket 12 to outer sides of the two side walls 113 of the cage body 11 and two inserting pieces 421 which protrude rearwardly from the two side extending pieces 420 respectively, two bulges 422 which are respectively formed to the two side walls 113 of the cage body 11, and two inserting holes 423 which are constructed to the two bulges 422 and are opened toward the front, the two inserting pieces 421 respectively rearwardly insert into the two inserting holes 423 on the two bulges 422. In the first embodiment, the two inserting pieces 421 extend out from the first side plates 125a of the upper frame 125 respectively.

The rear assembling construction 43 is provided between a rear end of the bottom plate 122 of the heat sink bracket 12 and the top wall 111 of the cage body 11. The rear assembling construction 43 includes a rear latching piece 431 which extends downwardly from the rear end of the bottom plate 122 of the heat sink bracket 12, and a rear latching groove 432 which is formed to the top wall 111 of the cage body 11, the rear latching piece 431 is used to downwardly latch to the rear latching groove 432.

The sideward position-limiting construction 44 is provided between two sides of the bottom plate 122 of the heat sink bracket 12 and the two side walls 113 of the cage body 11. The sideward position-limiting construction 44 includes sideward position-limiting pieces 441 which respectively bend downwardly and inwardly from the two sides of the bottom plate 122 of the heat sink bracket 12 and are respectively positioned to the outer sides of the two side walls 113 of the cage body 11.

The heat sink module 3 is provided in the heat sink receiving space 120 of the heat sink bracket 12. The heat sink module 3 includes a heat sink 31, a pressure-applying spring 32 and two restoring springs 33. The heat sink 31 has a base seat 311, heat dissipating fins 312 which are arranged side by side along the left-right direction D3, latch with each other and are provided to a top surface of the base seat 311, a thermal contact portion 313 which integrally protrudes downwardly from a bottom surface of the base seat 311 and is used to extend into the inserting passageway 115 via the frame mouth 122a and the window 111a, and a pushed portion 314 which integrally extends downwardly from the bottom surface of the base seat 311 to a position which is lower than the thermal contact portion 313 so as to extend into the inserting passageway 115 via the frame mouth 122a and the window 111a. For example, the pushed portion 314 is adjacent to a rear end of the thermal contact portion 313. In the first embodiment, the base seat 311 has a bottom portion 311a and two side portions 311b. The thermal contact portion 313 has a protruding block 313a which protrudes downwardly, and a thermal conductive pad 313b which is provided to a bottom surface of the protruding block 313a. The thermal conductive pad 313b for example may be a thermal interface material, the thermal interface material is capable of filling seams or gaps of contact surfaces to reduce a contact thermal resistance between the contact surfaces, the thermal interface material may be selected from, for example, a combination of materials with performances, such as high thermal conductivity, high flexibility, compressibility, insulation, abrasion resistance, etc. al, and for example, can be a combination of a substrate and a phase change material, and, for example, can be two or more layers configuration, an outer layer substrate of which can be a material (such as Teflon) with thermal conductivity, lubricity, abrasion resistance and tear resistance, and an inner layer material of which can be a phase change material. In addition, the thermal interface material may also have an electromagnetic wave shielding effect (EMI Shielding) at the same time by changing a combination of materials.

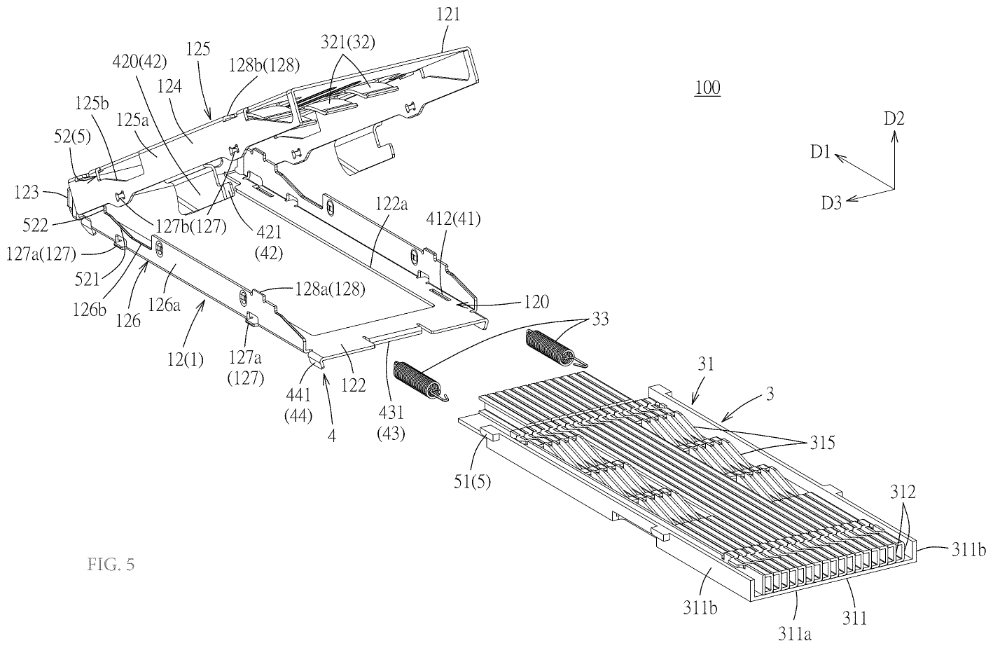

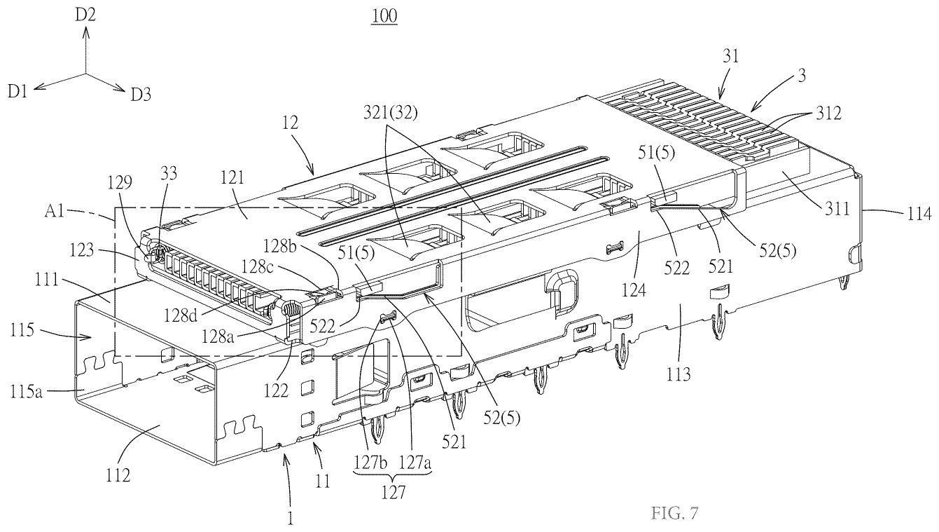

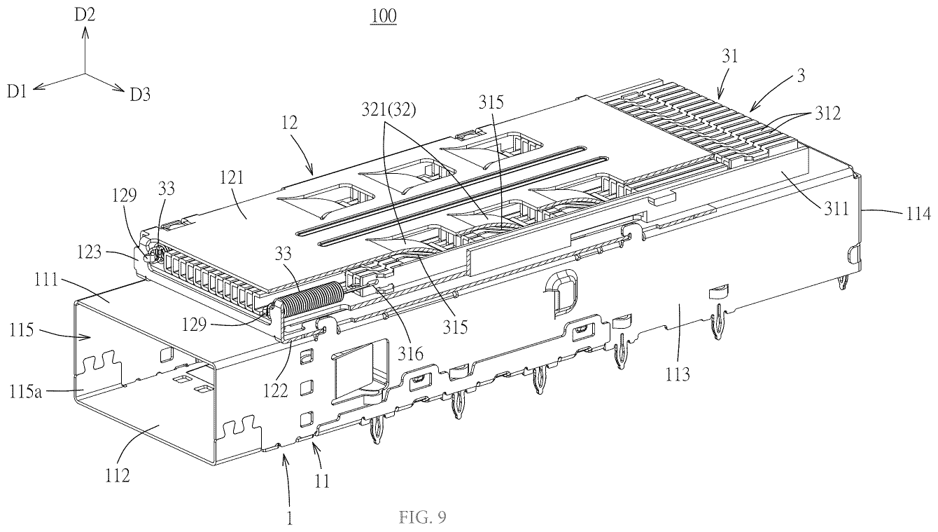

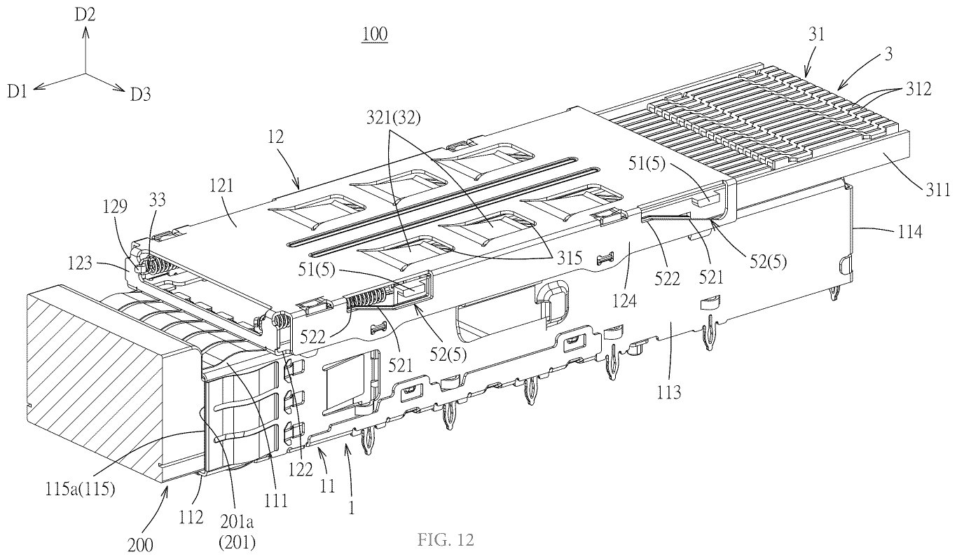

Referring to FIG. 5 to FIG. 9, the heat sink 31 and the heat sink bracket 12 are provided therebetween with a guiding construction 5, the guiding construction 5 guides the heat sink 31 to move between a first position (see FIG. 7) which is at relative front and up and a second position (see FIG. 12) which is at relative rear and down. The guiding construction 5 includes guiding pins 51 and guiding holes 52 which cooperate with each other. The guiding pins 51 are constructed to side surfaces of the heat sink 31 and protrude outwardly. The guiding holes 52 are constructed to the two side plates 124 of the heat sink bracket 12 and respectively accommodate the guiding pins 51. Each guiding hole 52 has a guiding rail 521 which is constituted by a lower profile of the guiding hole 52 and obliquely extends rearwardly and downwardly, and a positioning rail 522 which is positioned in front of and above the guiding rail 521 and extends forwardly. Each guiding pin 51 is capable of moving along the corresponding guiding rail 521 and the positioning rail 522 to guide the heat sink 31 to move between the first position and the second position, when the heat sink 31 is positioned at the first position, at least a part (a front end) of each guiding pin 51 is positioned in the corresponding positioning rail 522, the positioning rail 522 can assure the heat sink 31 to be positioned at the first position. Specifically, a lower end of each guiding pin 51 is capable of resting on the corresponding guiding rail 521, but an upper end of each guiding pin 51 is not limited, therefore, in one part of movement of the heat sink 31 from the first position to the second position, the guiding pins 51 are capable of moving along the guiding rails 521 respectively, in the other part of movement of the heat sink 31 from the first position to the second position behind the one part, the guiding pins 51 may be separated from the guiding rails 521 respectively. The first side plate 125a of the upper frame 125 and the second side plate 126a of the lower frame 126 are provided therebetween with a first opened hole 125b and a second opened hole 126b respectively to together constitute the guiding hole 52. In the first embodiment, the guiding rail 521 and the positioning rail 522 may be defined to the second opened hole 126b of the second side plate 126a of the lower frame 126, but in other varied implementing manners, may be defined to the first opened hole 125b of the first side plate 125a of the upper frame 125, or may be defined together by the first opened hole 125b and the second opened hole 126b.

Referring to FIG. 5 to FIG. 8, the pressure-applying spring 32 is provided between the top plate 121 of the heat sink bracket 12 and the heat sink 31. The pressure-applying spring 32 includes plate springs 321 which are integrally constructed to the top plate 121 of the heat sink bracket 12, the plate springs 321 extend rearwardly and downwardly. The heat sink 31 is constructed with pressure-applying spring acting portions 315 which are positioned on the heat dissipating fins 312 of the heat sink 31, the pressure-applying spring acting portions 315 respectively correspondingly cooperate with the plate springs 321, and each pressure-applying spring acting portion 315 includes an oblique pushing surface which extends rearwardly and downwardly.

The two restoring springs 33 be provided between the front end of the heat sink bracket 12 and a front end of the heat sink 31, the two restoring springs 33 are used to elastically deform when the heat sink 31 moves rearwardly so as to provide an elastic acting force which makes the heat sink 31 to move to the first position. The heat sink bracket 12 has two first hook portions 129 which are positioned at the front end of the heat sink bracket 12 and are constitute by bent piece structures, the heat sink 31 has two second hook portions 316 which are positioned at front ends of the heat dissipating fins 312 and are constituted by hole structures. The two restoring springs 33 are constructed as coil springs, front ends of the two restoring springs 33 respectively connect the two first hook portions 129 at the front end of the heat sink bracket 12, rear ends of the two restoring springs 33 respectively connect the two second hook portions 316 at the front ends of the heat sink 31, when the heat sink 31 moves rearwardly, the two restoring springs 33 are stretched to be elastically deformed, so as to provide an elastic acting force which is toward the front. Because the two restoring springs 33 are provided at the front ends of the heat sink 31, the heat sink 31 can elongate rearwardly without limitation to increase heat dissipating length and area in design.

Hereinafter a cooperating relationship between the pluggable module 200 and the heat sink module 3 is described.

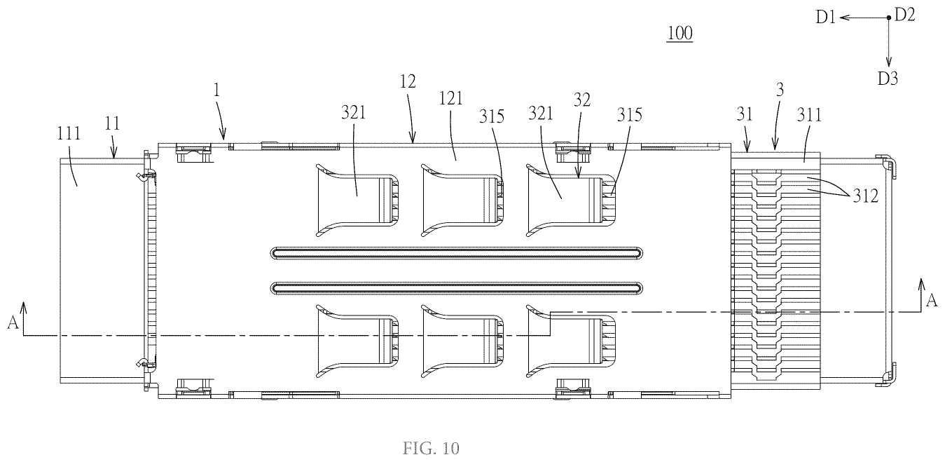

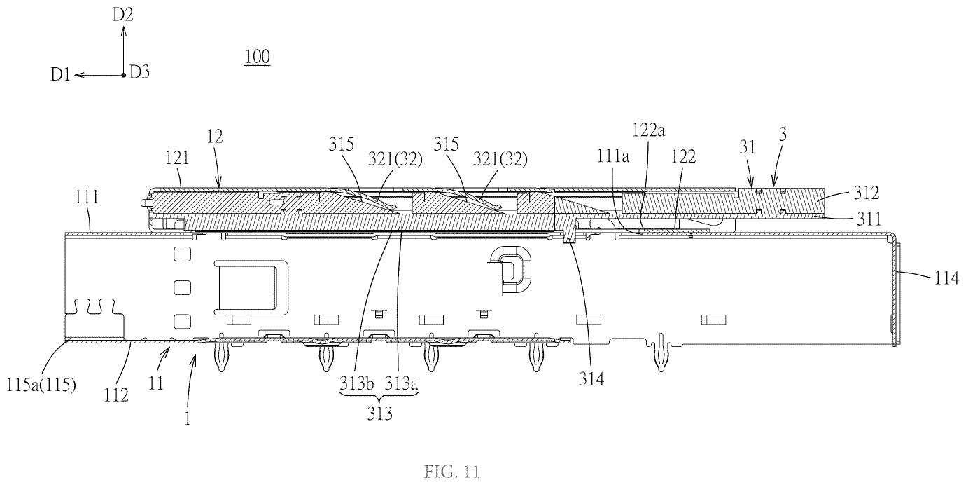

Referring to FIG. 7 to FIG. 11, before the pluggable module 200 (see FIG. 1) inserts into the inserting passageway 115 of the guide shielding cage 1, the heat sink 31 is positioned at the first position due to the elastic acting force provided by the two restoring springs 33, the guiding pins 51 on the heat sink 31 are positioned in the corresponding positioning rails 522, at this time, the plate springs 321 of the pressure-applying spring 32 are respectively positioned on rear ends (lower ends) of the oblique pushing surfaces of the pressure-applying spring acting portions 315 of the heat sink 31. It is noted that, after the pluggable module 200 partially inserts into the inserting passageway 115 but before pushes the pushed portion 314, the heat sink 31 is positioned at the first position, the thermal contact portion 313 at a bottom portion of the heat sink 31 does not contact a surface of the pluggable module 200 and has a gap with the pluggable module 200 therebetween, even the thermal contact portion 313 at the bottom portion of the heat sink 31 may leave the inserting passageway 115, therefore it may avoid a friction situation between the bottom portion of the heat sink 31 and the pluggable module 200 in an inserting process of the pluggable module 200 being generated, prevent wearing problem of the bottom portion of the heat sink 31.

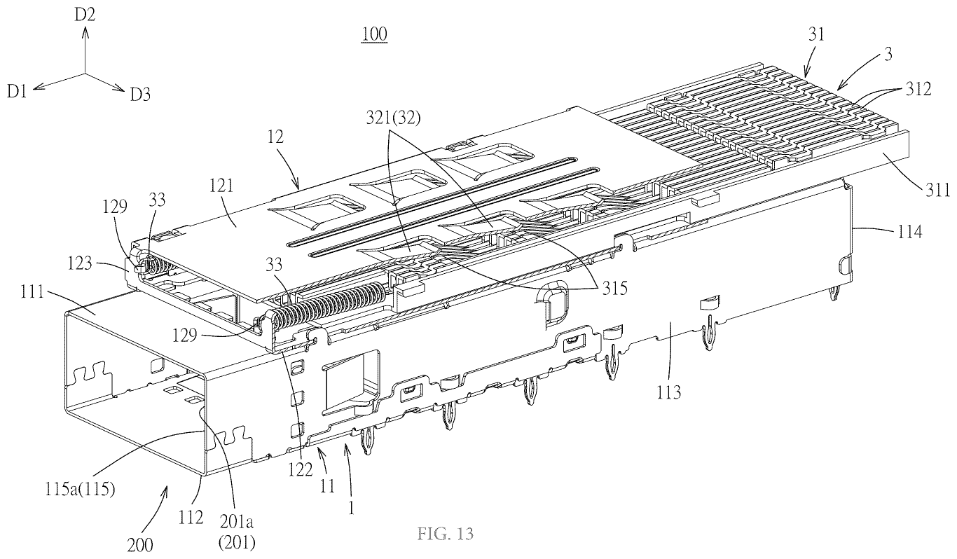

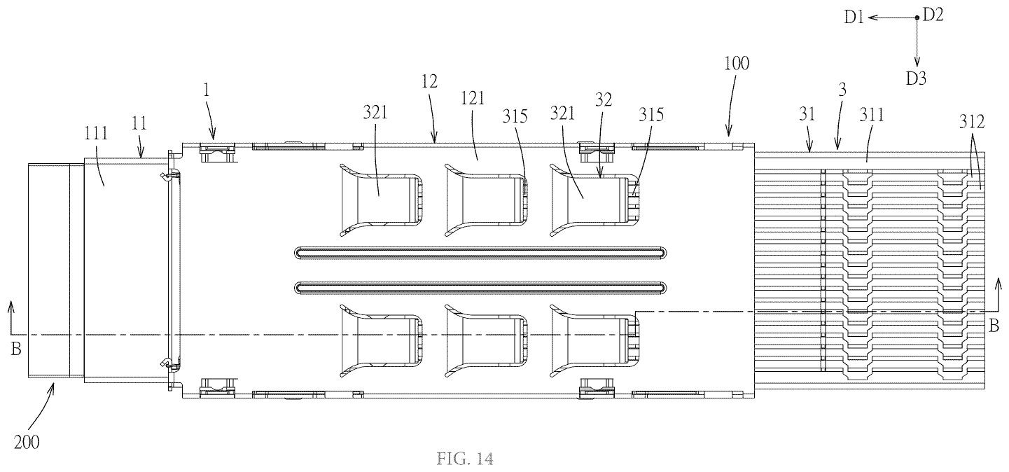

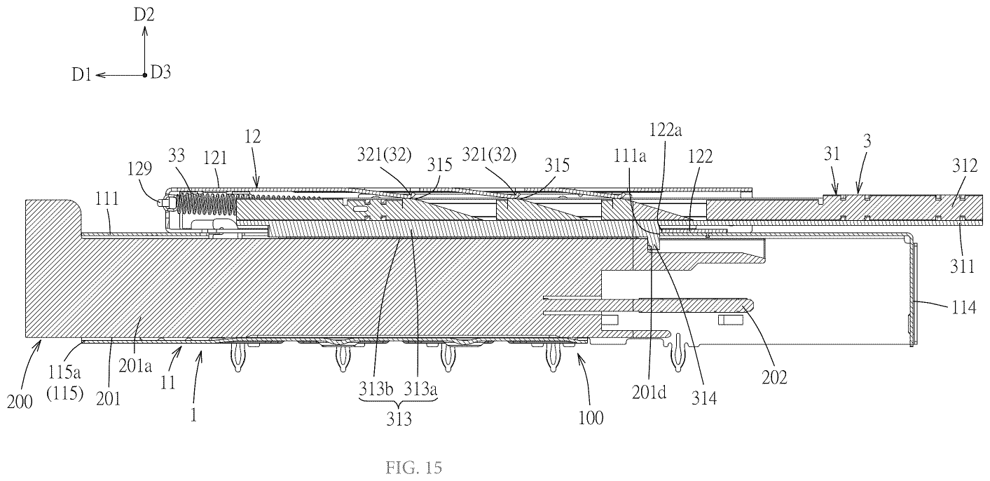

Referring to FIG. 12 to FIG. 15, when the pluggable module 200 inserts into the inserting passageway 115 of the guide shielding cage 1 along an inserting direction from front to rear, the pushing surface 201d of the pluggable module 200 pushes the pushed portion 314 of the heat sink 31 to move rearwardly, and makes the heat sink 31 move rearwardly and downwardly from the first position to the second position, in a process that the heat sink 31 moves rearwardly, the oblique pushing surfaces of the pressure-applying spring acting portions 315 push the plate springs 321 to be elastically deformed upwardly, so that the plate springs 321 downwardly apply downward acting forces to the heat sink 31, the guiding pins 51 on the heat sink 31 are respectively separated rearwardly from the positioning rails 522 and downwardly and rearwardly move against the guiding rails 521 respectively. When the heat sink 31 is at the second position, front ends (upper ends) of the oblique pushing surfaces of the pressure-applying spring acting portions 315 move to below the plate springs 321 of the pressure-applying spring 32, that is, the plate springs 321 apply forces to top surfaces of the heat dissipating fins 312 respectively at the front ends of the oblique pushing surfaces of the pressure-applying spring acting portions 315, because the pressure-applying spring acting portions 315 actuate the plate springs 321 of the pressure-applying spring 32 to be elastically deformed upwardly, so that the plate springs 321 of the pressure-applying spring 32 generate and apply downward elastic forces to the pressure-applying spring acting portions 315 respectively, the elastic acting forces of the pressure-applying spring 32 make the thermal contact portion 313 at the bottom portion of the heat sink 31 downwardly contact the surface of the pluggable module 200 with an elastic pressure. It is noted that, during movement after the heat sink 31 presses on the surface of the pluggable module 200, the guiding pins 51 are capable of being separated from the guiding rails 521. Moreover, after the heat sink 31 rearwardly moves to the second position, the two restoring springs 33 are stretched to generate elastic deformation.

Referring to FIG. 7 to FIG. 9, when the pluggable module 200 is withdrawn from the inserting passageway 115, elastic restoring forces of the two restoring springs 33 generated due to stretching drive the heat sink 31 to move forwardly from the second position back to the first position.

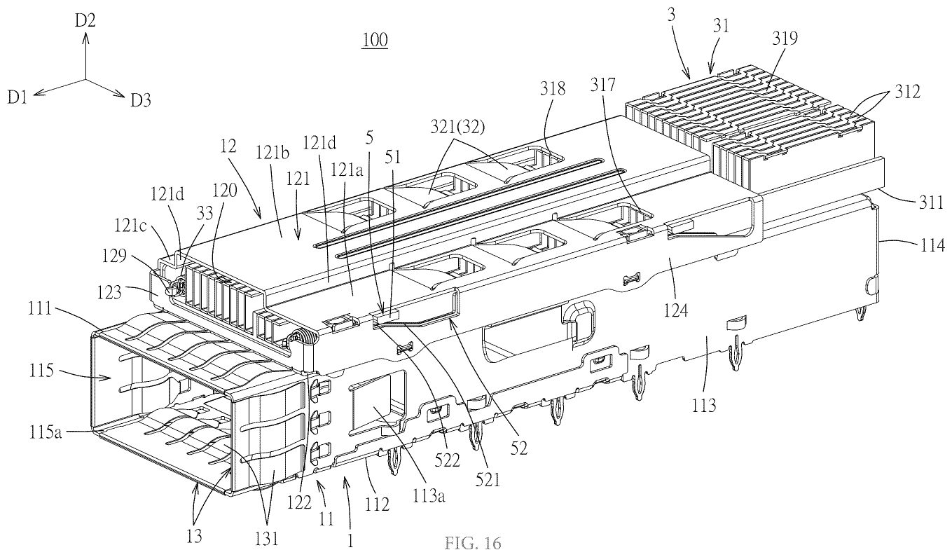

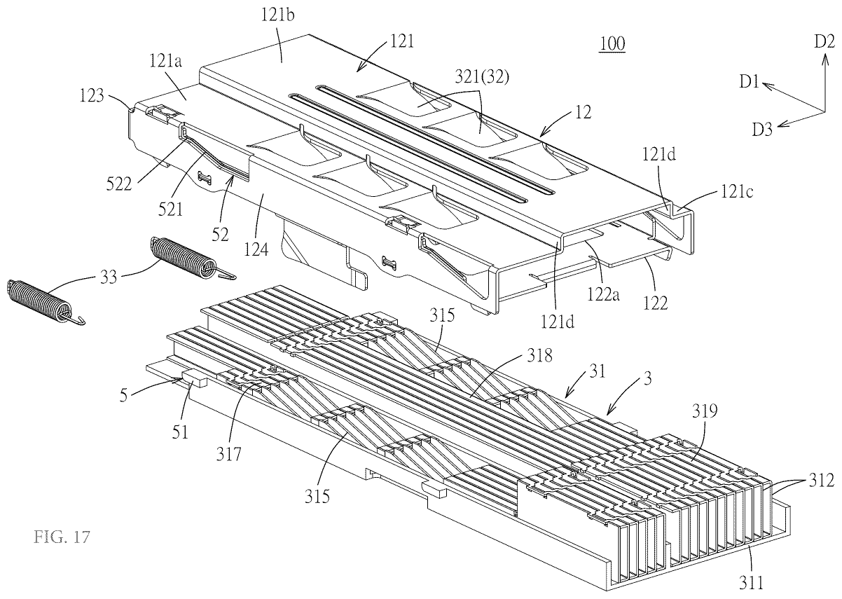

Referring to FIG. 16 to FIG. 17, a second embodiment of the connector assembly 100 of the present disclosure differs from the first embodiment in that, the heat dissipating fins 312 of the heat sink 31 constitute a first step portion 317 and a second step portion 318 which are arranged side by side along the left-right direction D3 and have heights of top portions thereof to be different, and a third step portion 319 which is positioned behind the first step portion 317 and the second step portion 318 and has a height of a top portion thereof to be higher than the first step portion 317 and the second step portion 318. The first step portion 317 and the second step portion 318 are positioned in the heat sink receiving space 120 of the heat sink bracket 12, and the height of the second step portion 318 is higher than the first step portion 317, the third step portion 319 is positioned outside a rear end of the heat sink receiving space 120 of the heat sink bracket 12 and the top portion of the third step portion 319 is higher than the top plate 121 of the heat sink bracket 12. The top plate 121 has a first plate portion 121a, a second plate portion 121b and a third plate portion 121c which are sequentially arranged along the left-right direction D3, and two step connecting portions 121d which are respectively connected between the first plate portion 121a and the second plate portion 121b and between the second plate portion 121b and the third plate portion 121c. The first plate portion 121a corresponds to the first step portion 317 of the heat sink 31, the second plate portion 121b corresponds to the second step portion 318 of the heat sink 31 and a height of the second plate portion 121b is higher than the first plate portion 121a, a height of the third plate portion 121c is substantially the same as a height of the first plate portion 121a.

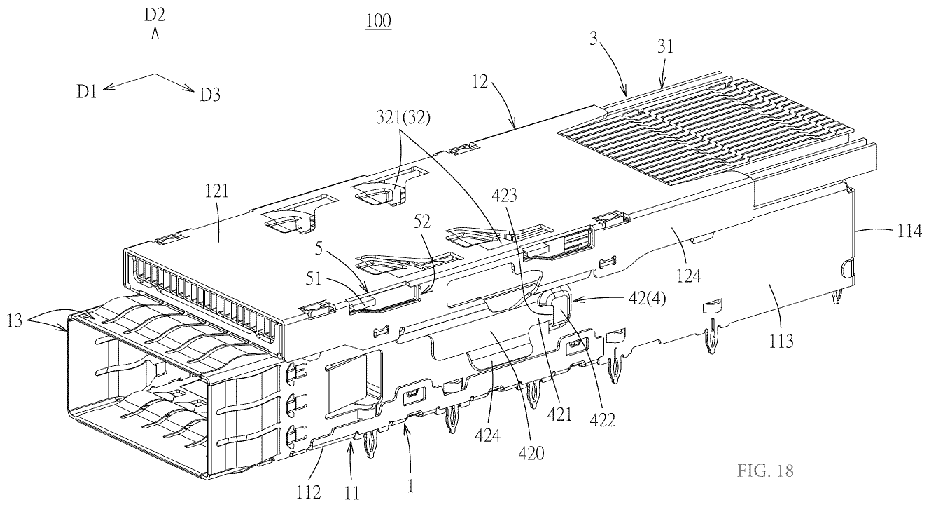

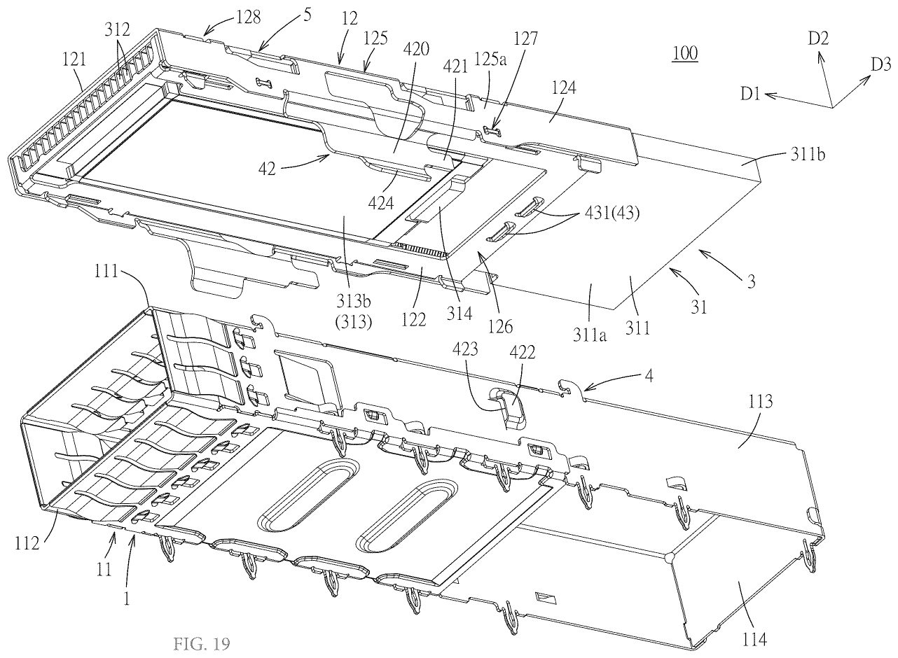

Referring to FIG. 18 to FIG. 20, a third embodiment of the connector assembly 100 of the present disclosure differs from the first embodiment of in that, the pressure-applying spring acting portions 315 are positioned at inner sides of the two side portions 311b of the base seat 311 and are constructed on the base seat 311, and each the pressure-applying spring acting portion 315 includes an oblique pushing surface which extends rearwardly and downwardly, in the third embodiment, the oblique pushing surface is constituted by a curved surface which protrudes.

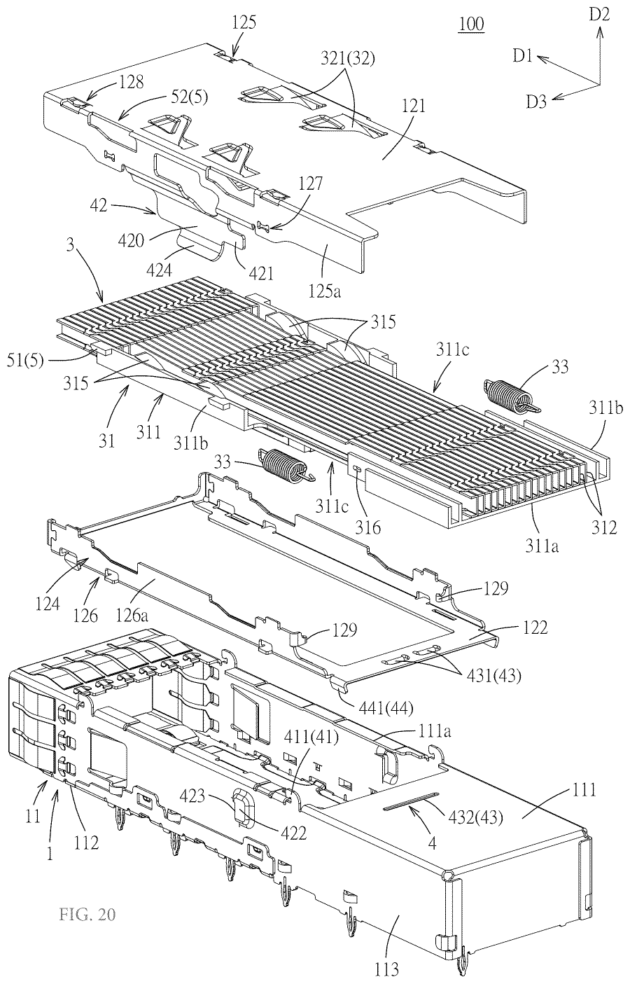

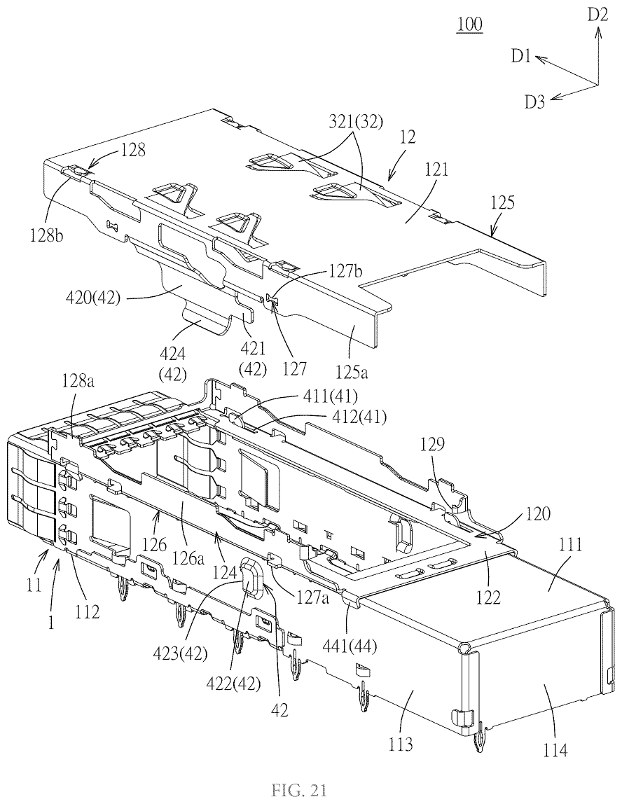

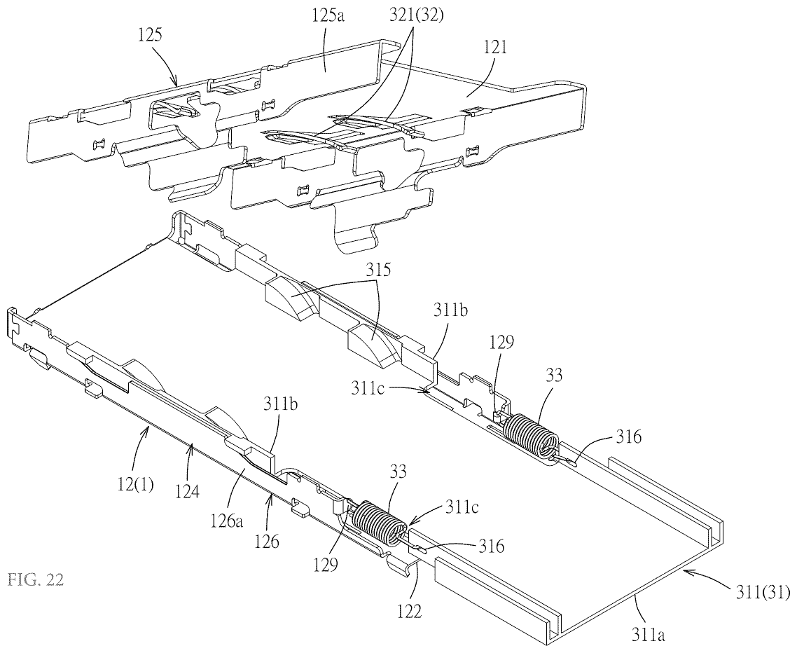

Referring to FIG. 20 to FIG. 22, in addition, the two restoring springs 33 are provided between the two side plates 124 of the heat sink bracket 12 and the two side portions 311b of the heat sink 31. Each side plate 124 of the heat sink bracket 12 has the first hook portion 129 which is constituted by a bent piece structure, in the third embodiment, the first hook portion 129 is integrally constructed on the second side plate 126a of the lower frame 126. Each side portion 311b of the base seat 311 of the heat sink 31 has a notch 311c and a second hook portion 316 which is positioned behind the notch 311c and is constituted by a hole structure, the first hook portion 129 extends into the notch 311c, the restoring spring 33 is positioned in the notch 311c, the front end of the restoring spring 33 connects the first hook portion 129, the rear end of the restoring spring 33 connects the second hook portion 316.

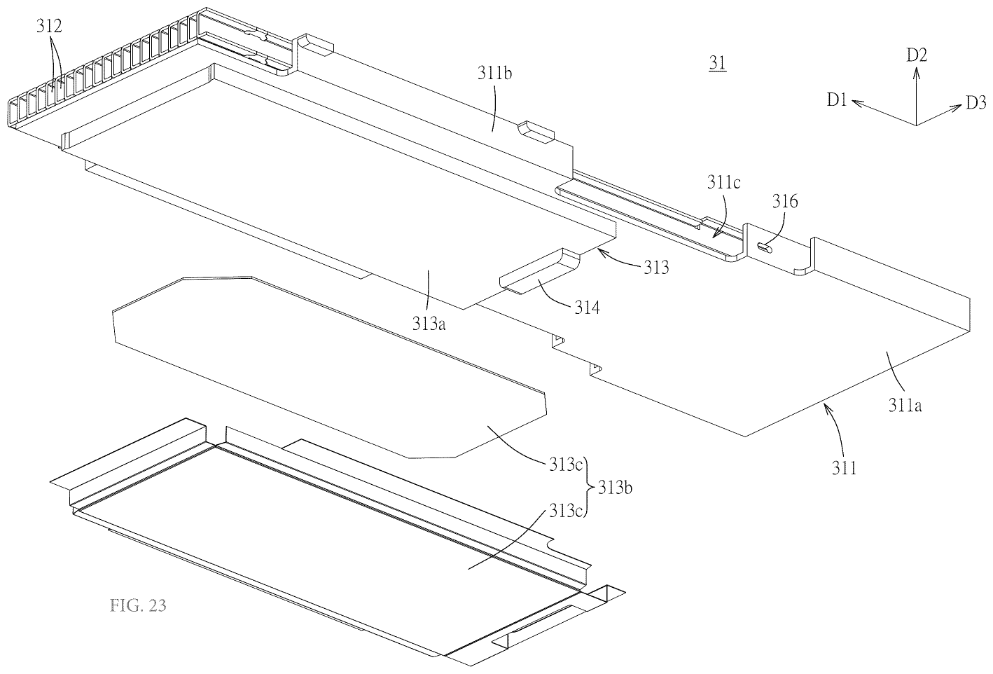

Referring to FIG. 20 to FIG. 23, moreover, in the third embodiment, the upper frame 125 and the lower frame 126 of the heat sink bracket 12 are two components which are independent and separated from other. The rear assembling construction 43 includes two rear latching pieces 431 which extend downwardly from the rear end of the bottom plate 122 of the heat sink bracket 12, and one rear latching groove 432 which is formed to the top plate 111 of the cage body 11, the two rear latching pieces 431 are used to downwardly latch to the rear latching groove 432.

Moreover, the side assembling construction 42 further includes two grasping pieces 424 which extend downwardly from the two side extending pieces 420 respectively and splay. The thermal conductive pad 313b includes two thermal conductive layers 313c which overlap with each other.

In conclusion, in the present disclosure, by that the pressure-applying spring 32, which is provided between the heat sink bracket 12 and the heat sink 31, directly applies an elastic force to the heat sink 31, and by that the guiding construction 5, which is between the heat sink 31 and the heat sink bracket 12, pushes and guides the heat sink 31 to move rearwardly and downwardly to the second position, as such, after inserting of the pluggable module 200, can the heat sink 31 move to a position where the heat sink 31 contacts the surface of the pluggable module 200, so as to avoid the bottom portion of the heat sink 31 and the pluggable module 200 therebetween generating a friction situation in an inserting process of the pluggable module 200, prevent wearing problem of the bottom portion of the heat sink 31, or prevent the thermal interface material provided to the bottom portion of the heat sink 31 from being scratched. In addition, the pressure-applying spring 32 is integrally constructed on the heat sink bracket 12, the pressure-applying spring acting portions 315 are integrally constructed on the heat sink 31 (the heat dissipating fins 312), which makes an entire heat dissipating assembly simplified and has a constructive effect of low profile. Furthermore, because the guiding construction 5 only provides a guiding function, but the pressure-applying spring 32 directly acts on the heat sink 31, so that the bottom portion of the heat sink 31 contacts the surface of the pluggable module 200 with the elastic pressure, heat conduction efficiency can be promoted and heat dissipating effect is increased, and hard interference situation between the heat sink 31 and the pluggable module 200 is prevented.

However, the above description is only for the embodiments of the present disclosure, and it is not intended to limit the implementing scope of the present disclosure, and the simple equivalent changes and modifications made according to the claims and the contents of the specification are still included in the scope of the present disclosure.

What is claimed is:

1. A connector assembly adapted to mate with a pluggable module, the connector assembly comprising:
a guide shielding cage comprising a cage body which has an inserting passageway, and a heat sink bracket which is positioned above the inserting passageway of the cage body, the heat sink bracket having a top plate; and
a heat sink module provided to the heat sink bracket, the heat sink module comprising a heat sink, a pressure-applying spring and a restoring spring; the heat sink having a pushed portion which extends into the inserting passageway, the pressure-applying spring being provided between the top plate of the heat sink bracket and the heat sink, the restoring spring being provided between the heat sink bracket and the heat sink, the heat sink and the heat sink bracket being provided therebetween with a guiding construction, the guiding construction guiding the heat sink to move between a first position which is at relative front and up and a second position which is at relative rear and down;
when the pluggable module inserts into the inserting passageway of the guide shielding cage along an inserting direction from front to rear, the pluggable module pushing the pushed portion of the heat sink and making the heat sink move from the first position to the second position, when the heat sink is at the second position, an elastic acting force of the pressure-applying spring making a bottom portion of the heat sink downwardly contact a surface of the pluggable module with an elastic pressure;
when the pluggable module is withdrawn from the inserting passageway, the restoring spring driving the heat sink to move from the second position back to the first position.

2. The connector assembly of claim 1, wherein
the heat sink bracket further has side plates,
the guiding construction comprises guiding pins and guiding rails which cooperate with each other,
the guiding rails are constructed to the side plates of the heat sink bracket and obliquely extend rearwardly and downwardly,
the guiding pins are constructed to side surfaces of the heat sink, the guiding pins are capable of moving along the guiding rails respectively.

3. The connector assembly of claim 2, wherein
the guiding construction further comprises guiding holes which are constructed to the side plates of the heat sink bracket and accommodate the guiding pins respectively,
the guiding hole has the guiding rail constituted by a lower profile of the guiding hole, and a positioning rail which is positioned in front of and above the guiding rail and extends forwardly, when the heat sink is positioned at the first position, at least a part of the guiding pin is positioned in the corresponding positioning rail.

4. The connector assembly of claim 1, wherein
the pressure-applying spring comprises plate springs which integrally constructed to the top plate of the heat sink bracket, the plate springs extend rearwardly and downwardly;
the heat sink is constructed with pressure-applying spring acting portions,
when the heat sink moves rearwardly and downwardly from the first position, the pressure-applying spring acting portions actuate the pressure-applying spring to be elastically deformed so that the pressure-applying spring generates and applies a downward elastic force to the pressure-applying spring acting portions.

5. The connector assembly of claim 4, wherein
the heat sink has heat dissipating fins, the pressure-applying spring acting portions are constructed on the heat dissipating fins of the heat sink, and comprise oblique pushing surfaces which extend rearwardly and downwardly.

6. The connector assembly of claim 4, wherein
the heat sink has a base seat, the pressure-applying spring acting portions are constructed on the base seat and comprise oblique pushing surfaces which extend rearwardly and downwardly.

7. The connector assembly of claim 1, wherein
the restoring spring is provided between a front end of the heat sink bracket and a front end of the heat sink,
when the heat sink moves rearwardly, the restoring spring is elastically deformed so as to provide an elastic acting force which makes the heat sink move to the first position.

8. The connector assembly of claim 7, wherein
the heat sink bracket has a first hook portion which is positioned at the front end of the heat sink bracket,
the heat sink has a second hook portion is positioned at the front end of the heat sink,
a front end of the restoring spring connects the first hook portion at the front end of the heat sink bracket, a rear end of the restoring spring connects the second hook portion at the front end of the heat sink.

9. The connector assembly of claim 1, wherein
the heat sink bracket further has a side plate,
the heat sink further has a side portion,
the restoring spring is provided between the side plate of the heat sink bracket and the side portion of the heat sink,
when the heat sink moves rearwardly, the restoring spring is elastically deformed so as to provide an elastic acting force which makes the heat sink move to the first position.

10. The connector assembly of claim 9, wherein
the side plate of the heat sink bracket has a first hook portion,
the side portion of the heat sink has a notch and a second hook portion which is positioned behind the notch,
the first hook portion extends into the notch,
the restoring spring is positioned in the notch, a front end of the restoring spring connects the first hook portion, a rear end of the restoring spring connects the second hook portion.

11. The connector assembly of claim 8, wherein
the restoring spring is constructed as a coil spring, when the heat sink moves rearwardly, the restoring spring is stretched to be elastically deformed.

12. The connector assembly of claim 1, wherein
when the heat sink is positioned at the first position, the bottom portion of the heat sink does not contact the surface of the pluggable module.

13. The connector assembly of claim 1, wherein
the heat sink further has a base seat, heat dissipating fins which are provided a top surface of the base seat, and a thermal contact portion which protrudes downwardly from a bottom surface of the base seat,
the pushed portion is positioned at a rear end of the thermal contact portion, the pushed portion extends downwardly from the bottom surface of the base seat to a position which is lower than the thermal contact portion.

14. The connector assembly of claim 13, wherein
the thermal contact portion of the heat sink comprises a thermal conductive pad.

15. The connector assembly of claim 1, wherein
the heat sink bracket comprises an upper frame and a lower frame,
the upper frame has the top plate and first side plates,
the lower frame has a bottom plate and second side plates,
the first side plates of the upper frame and the second side plates of the lower frame are provided therebetween with a latching construction which allows the first side plates of the upper frame and the second side plates of the lower frame to latch with each other and an aligning construction which allows the first side plates of the upper frame and the second side plates of the lower frame to mate with each other.

16. The connector assembly of claim 15, wherein
the latching construction comprises latching pieces and latching holes which latch with each other, the latching pieces are provided on the second side plates of the lower frame, the latching holes are provided on the first side plates of the upper frame;
the aligning construction comprises aligning pieces and aligning holes which mate with each other, the aligning pieces are provided to upper edges of the second side plates of the lower frame and extend upwardly, the aligning holes are provided to the top plate of the upper frame at locations of the top plate of the upper frame which are respectively close to the first side plates,
the first side plates of the upper frame are positioned at outer sides of the second side plates of the lower frame respectively,
the aligning pieces insert into the aligning holes respectively;
a position-limiting piece is provided at an inner side of the corresponding aligning hole and is recessed, the position-limiting piece is lower than a position of a top portion of the corresponding aligning piece.

17. The connector assembly of claim 16, wherein
the position-limiting piece which is recessed has a protruding edge which extends toward corresponding the aligning piece.

18. The connector assembly of claim 1, wherein
the cage body of the guide shielding cage further has a top wall and side walls which together define the inserting passageway,
the heat sink bracket further has a bottom plate and side plates,
the heat sink bracket is provided to the top wall,
the heat sink bracket and the cage body are provided therebetween with a bracket assembling construction,
the bracket assembling construction comprises a bottom assembling construction, a side assembling construction and a rear assembling construction,
the bottom assembling construction is provided between a left side and a right side of the bottom plate of the heat sink bracket and a left side and a right side of the top wall of the cage body,
the side assembling construction is provided between the side plates of the heat sink bracket and the side walls of the cage body,
the rear assembling construction is provided between a rear end of the bottom plate of the heat sink bracket and the top wall of the cage body.

19. The connector assembly of claim 18, wherein
the bottom assembling construction comprises snapping hooks which extend out from the top wall of the cage body,
the bottom plate of the heat sink bracket snaps onto the snapping hooks.

20. The connector assembly of claim 19, wherein
the bottom assembling construction further comprises snapping hook apertures which are constructed to the bottom plate of the heat sink bracket,
openings of the snapping hooks are toward the front, after the snapping hooks pass through the snapping hook apertures, the heat sink bracket moves rearwardly, so as to make the bottom plate snap into the snapping hooks.

21. The connector assembly of claim 18, wherein
the side assembling construction comprises side extending pieces which extend from the side plates of the heat sink bracket to outer sides of the side walls of the cage body and inserting pieces which protrude rearwardly from the side extending pieces respectively, bulges which are formed to the side walls of the cage body, and inserting holes which are constructed to the bulges and are opened toward the front,
the inserting pieces rearwardly insert into the inserting holes respectively.

22. The connector assembly of claim 18, wherein
the rear assembling construction comprises a rear latching piece which extends downwardly from a rear end of the bottom plate of the heat sink bracket, and a rear latching groove which is formed to the top wall of the cage body,
the rear latching piece is used to downwardly latch to the rear latching groove.

23. The connector assembly of claim 18, wherein
the bracket assembling construction further comprises a sideward position-limiting construction which is provided between the two sides of the bottom plate of the heat sink bracket and the side walls of the cage body;
the sideward position-limiting construction comprises sideward position-limiting pieces which bend downwardly from the two sides of the bottom plate of the heat sink bracket and are respectively positioned to outer sides of the two side walls of the cage body.
